(19) United States
(12) Patent Application Publication
(10) Pub. No.: US 2011/0195560 A1
(43) Pub. Date: Aug. 11, 2011

(54) METHOD OF PRODUCING A SILICON-ON-SAPPHIRE TYPE HETEROSTRUCTURE

(75) Inventors: Gweltaz Gaudin, Grenoble (FR); Alexandre Vaufredaz, La Murette (FR); Fleur Guittard, Brie Et Angonnes (FR)

(73) Assignee: S.O.I.TEC SILICON ON INSULATOR TECHNOLOGIES, Crolles Cedex (FR)

(21) Appl. No.: 13/123,180

(22) PCT Filed: Nov. 19, 2009
(86) PCT No.: PCT/EP09/65440

§ 371 Date: Apr. 7, 2011

(30) Foreign Application Priority Data
Nov. 24, 2008 (FR) 0857954

(51) Int. Cl. H01L 21/762

(52) U.S. Cl. 438/459; 257/E21.567

(57) ABSTRACT

The invention provides a method of producing a heterostructure of the silicon-on-sapphire type, comprising bonding an SOI substrate onto a sapphire substrate and thinning the SOI substrate, thinning being carried out by grinding followed by etching of the SOI substrate. In accordance with the method, grinding is carried out using a wheel with a grinding surface that comprises abrasive particles having a mean dimension of more than 6.7 μm; further, after grinding and before etching, the method comprises a step of post-grinding annealing of the heterostructure carried out at a temperature in the range of 150° C. to 170° C.

### CROSS-REFERENCE TO RELATED APPLICATIONS

This is a national phase entry under 35 U.S.C. §371 of International Patent Application PCT/EP2009/065440, filed Nov. 19, 2009, published in English as International Patent Publication WO 2010/057941 A1 on May 27, 2010, which claims the benefit under Article 8 of the Patent Cooperation Treaty of French Patent Application Serial No. 0857954, filed Nov. 24, 2008, the entire disclosure of each of which is hereby incorporated herein by this reference.

### TECHNICAL FIELD

The present invention relates to the production of heterogeneous structures formed by bonding at least one substrate of semiconductor material, such as silicon, on a sapphire (Al₂O₃) substrate. In particular, the invention is applicable to the fabrication of silicon-on-sapphire type heterostructures known by the acronym SOS (for silicon-on-sapphire).

### BACKGROUND

Heterostructures comprising a layer of silicon on a sapphire substrate have particular advantages. SOS structures can produce high-frequency, low-energy-consumption devices. The use of sapphire substrates can also mean that very good heat dissipation can be achieved that is superior to that obtained with quartz substrates, for example.

SOS structures were initially produced by growing a layer of silicon epitaxially from a sapphire substrate. However, with that technique, it is difficult to obtain layers or films of silicon with a low crystal defect density due to the large differences between the lattice parameters and the thermal expansion coefficients of the two materials.

In accordance with another technique, SOS structures can be produced by assembling an SOI (silicon-on-insulator) structure on a sapphire substrate. In that technique, production of an SOS structure comprises bonding the SOI structure onto the sapphire substrate by direct wafer bonding or fusion bonding (also known as molecular adhesion), a reinforcing anneal or bonding stabilization anneal, and thinning the SOI structure to form a transferred layer of silicon on the sapphire substrate. Thinning is typically carried out in two steps, namely, a first grinding step that removes the major portion of the support substrate of the SOI structure, followed by a second step of chemical etching up to the oxide layer of the SOI structure that acts as a stop layer. Chemical etching is typically carried out using a TMAH (tetramethylammonium hydroxide) solution.

However, as shown in FIG. 1, after chemical etching, the heterostructure may have crosswise crack type defects disposed along the crystalline axes of the superficial silicon layer. Further, chemical etching may result in delamination of the transferred silicon layer, as can be seen in FIG. 2 where it should be observed that the superficial silicon layer and the subjacent sapphire substrate have delaminated when a shear force is applied to the silicon layer. Finally, as can be seen in FIG. 3, as well as in FIG. 1, edge loss defects (broadening of the ring due to delamination) are already present following grinding.

Crosswise crack type defects are probably already present following grinding, but are not detectable. They are, in fact, revealed by the TMAH solution. Edge loss type defects are due to delamination during bonding reinforcement annealing; the greater the thickness of the silicon at the moment of bonding reinforcement annealing, the wider are the edge loss defects.

The presence of defects and of delamination are principally due to the fact that direct wafer bonding between the sapphire substrate and the transferred silicon layer is not strong enough to prevent the etching solution from infiltrating into the bonding interface. Because of the large difference between the expansion coefficient of silicon and that of sapphire (3.6×10⁻⁶/° C. for silicon and 5×10⁻⁶/° C. for sapphire), large thermomechanical stresses are produced in the structure during post-bonding heat treatments such as reinforcing annealing, which causes cracks to appear and propagate in the silicon.

Further, as can be seen in FIG. 4, during heat treatment, the difference in the thermal expansion coefficients of silicon and sapphire results in deformation of the assembly such that high tensile stresses and shear stresses are applied to the edges of the heterostructure. Such stresses may entrain unbonding at the edges between the silicon layer and the sapphire substrate, which allows the etching solution to infiltrate into the bonding interface during thinning. The infiltration weakens the bond and may cause delamination of the structure, as shown above relative to FIG. 2.

Further, in order to avoid producing thermomechanical stresses in the heterostructure that are too high during bonding reinforcement annealing, the temperature thereof is limited (<300° C.) compared with the temperatures normally used during such anneals (700° C. to 800° C.). This limitation in temperature means that large bonding energy between the silicon and the sapphire cannot be obtained.

U.S. Pat. No. 5,395,788 describes a method of producing a heterostructure, comprising bonding a silicon substrate onto a quartz substrate. In order to prevent the appearance of defects and of delamination of the substrates, that document recommends carrying out thinning of the silicon substrate in several steps with heat treatments before and after each of those steps. The temperature of the heat treatments is raised continually as the treatments proceed.

Furthermore, silicon-on-sapphire bonding methods are described in the following documents:
G. P. Imthurn, G. A. Garcia, H. W. Walker, and L. Forbes, “Bonded Silicon-On-Sapphire Wafers and Devices,” J. Appl. Phys. 72(6), 15 Sep. 1992, pp. 2526-2527;
U.S. Pat. No. 5,441,591;
Takao Abe et al., “Dislocation-Free Silicon-on-sapphire By Wafer Bonding,” January 1994, Jpn J. Appl. Phys. vol. 33, pp. 514-518; and
Kopperschmidt et al., “High Bond Energy and Thermomechanical Stress in Silicon-on-Sapphire Wafer Bonding,” Appl. Phys. Lett. 70 (22), p 2972, 1997.

### BRIEF SUMMARY

One of the aims of the invention is to overcome the above-mentioned disadvantages by proposing a solution that can produce an SOS type heterostructure by bonding and thinning of an SOI substrate or structure on a sapphire substrate, thereby limiting the appearance of defects and the risk of delamination as described above.

To this end, the present invention proposes a method of producing such a heterostructure, in which thinning of the SOI substrate or structure is carried out by grinding followed by an etch, the method being characterized in that grinding is carried out using a wheel with a grinding surface that comprises abrasive particles having a mean dimension of more than 6.7 microns (or less than 2000 mesh), and in that the method comprises, after grinding and before etching, a step of post-grinding annealing of the heterostructure carried out at a temperature in the range 150° C. to 170° C.

Using a wheel or grinder for grinding that comprises abrasive particles having a mean dimension of more than 6.7 microns (μm) means that coarse grinding can be carried out, as opposed to fine grinding that is carried out with a wheel comprising abrasive particles having a mean dimension of less than 6.7 μm.

The applicants have elected to use such coarse grinding since it means that the SOI substrate can be thinned, thereby minimizing the risks of delamination between the SOI substrate and the sapphire substrate during grinding. Because the bond between these two elements is weak (limitation on the temperature of the reinforcement anneal), it is not possible to apply a very high load with the wheel during grinding without risking delamination. To this end, grinding carried out with abrasive particles having a mean dimension greater than at least 6.7 μm means that a large quantity of material can be removed without having to apply too high a load. During grinding, the load of the wheel on the SOI substrate does not exceed 222.5 newtons (N). In contrast, with abrasive particles of smaller dimensions, corresponding to fine grinding, the surface area ratio between the fine wheel and the material is higher than between the coarse wheel and that same material, which has the effect of increasing the load of the wheel on the SOI substrate and, as a result, of increasing the risks of delamination.

However, with a coarse grind (abrasive particles having a mean dimension of more than 6.7 μm), the SOI substrate has a work-hardened surface that is the origin of the appearance of crack type defects during subsequent heat treatments. By limiting the post-grinding annealing temperature to a temperature in the range of 150° C. to 170° C., the appearance of such defects is prevented.

Post-grinding annealing can also reinforce the bond between the sapphire substrate and the SOI substrate and thereby prevent infiltration of the etching solution into the bonding interface during the second thinning step.

A step of pre-grinding annealing of the heterostructure may also be carried out in order to reinforce bonding and further reduce the risks of delamination during grinding. The pre-grinding anneal is carried out at a temperature that is preferably in the range of 150° C. to 180° C. In accordance with one aspect of the invention, the boat-in temperature of the heterostructure during pre-grinding annealing is less than 80° C. In accordance with a further aspect, the temperature ramp-up is of the order of 1° C. per minute (° C./minute).

### BRIEF DESCRIPTION OF THE DRAWINGS

Other characteristics and advantages of the invention become apparent from the following description of particular implementations of the invention, given as non-limiting examples, made with reference to the accompanying drawings, in which:

FIG. 1 is a photograph showing edge loss type defects and showing crack type crosswise defects in a silicon-on-sapphire heterostructure after chemical etching;

FIG. 2 is a photograph showing the delamination of a silicon-on-sapphire heterostructure;

FIG. 3 is a photograph showing edge loss type defects and crosswise crack type defects in a silicon-on-sapphire heterostructure following grinding;

FIG. 4 illustrates the deformation undergone by a silicon-on-sapphire heterostructure during heat treatment;

FIGS. 5A to 5G are diagrammatic views showing the production of a heterostructure employing a method in accordance with the invention;

FIG. 6 is a flow chart of the steps carried out during production of the heterostructure illustrated in FIGS. 5A to 5G.

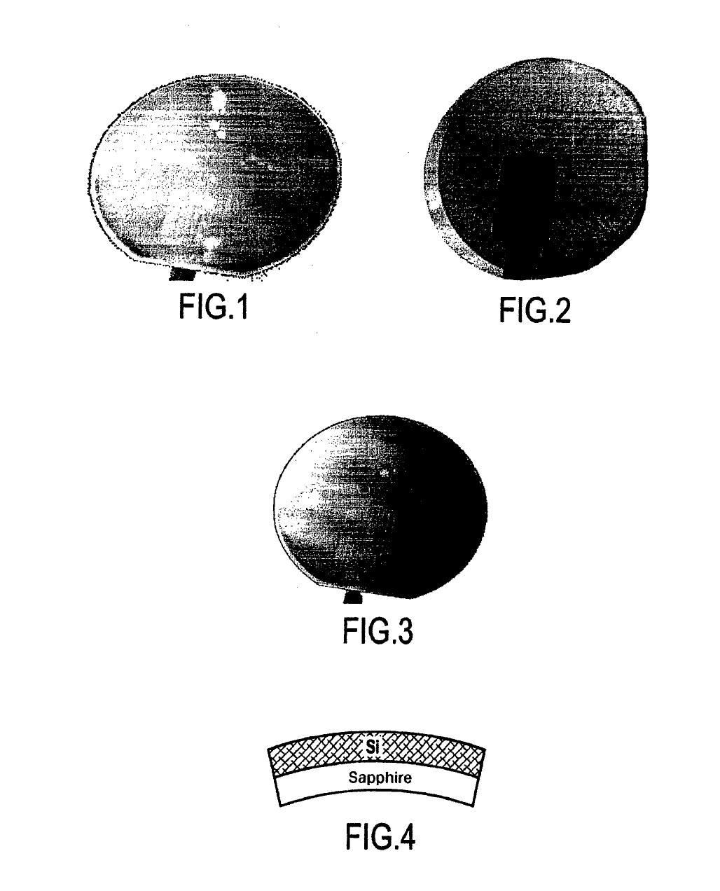

### DETAILED DESCRIPTION

The method of the present invention is of general application to the production of an SOS type heterostructure formed from an assembly between a first substrate formed of sapphire and a second substrate, or SOI substrate. The substrates may, in particular, have diameters of 150 millimeters (mm).

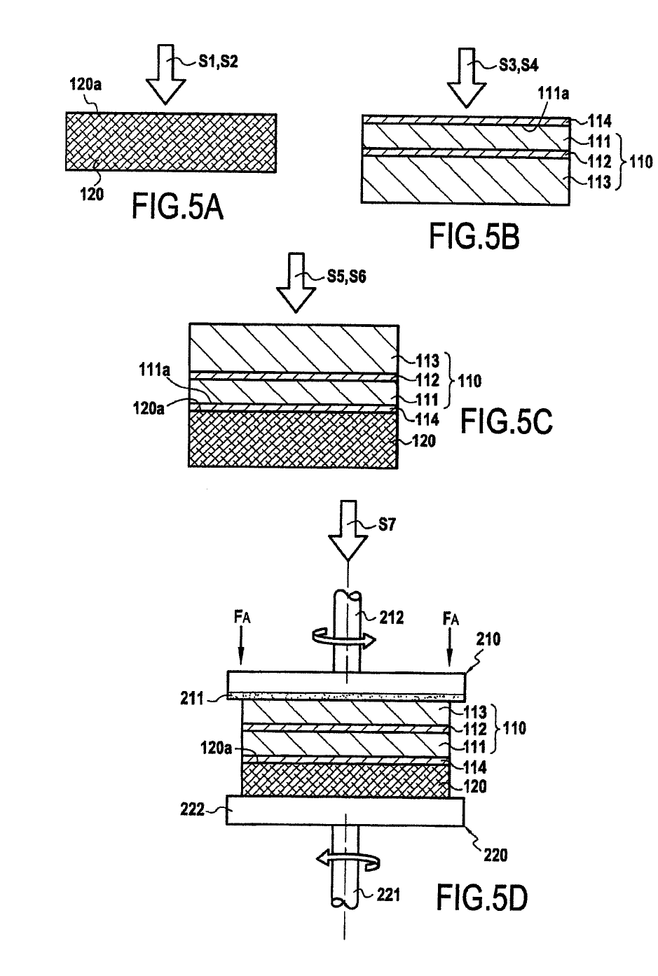

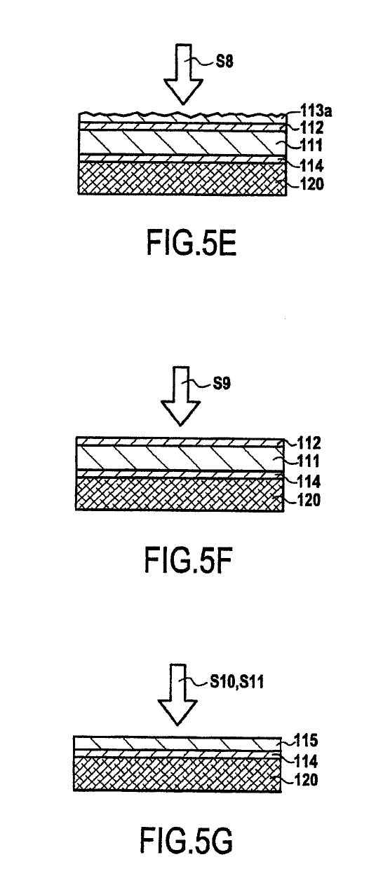

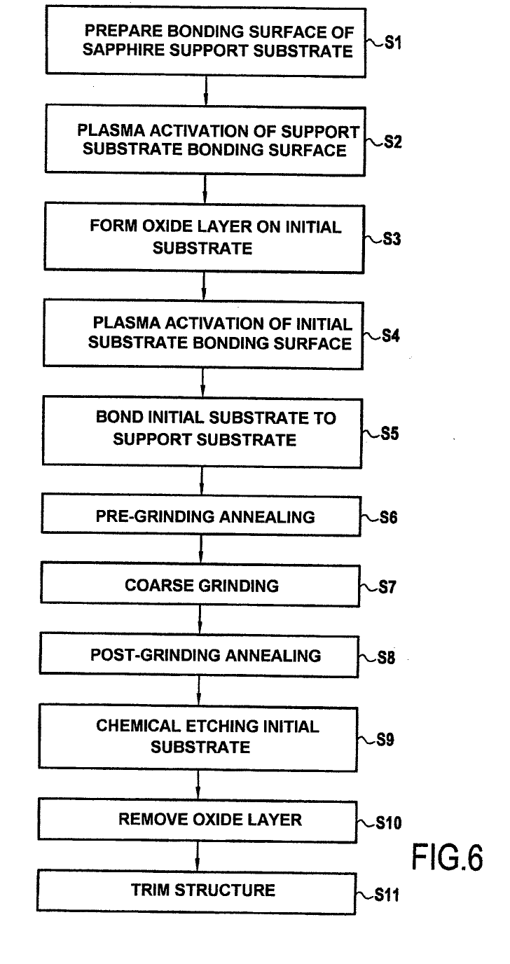

Referring to FIGS. 5A to 5G and 6, a method of producing an SOS type heterostructure from an initial substrate 110 (top) and a support substrate 120 (base) is described.

As can be seen in FIG. 5B, the initial substrate 110 is constituted by an SOI type structure comprising a layer of silicon 111 on a support 113, also of silicon, with a buried oxide layer 112, formed of SiO₂, for example, being disposed between the layer 111 and the support 113.

The support substrate 120 is constituted by a wafer of sapphire (FIG. 5A).

Before carrying out bonding of the initial substrate 110 to the support substrate 120, the bonding surface 120a of the sapphire support substrate that has been polished, typically by chemical-mechanical polishing (CMP), may be prepared (step S1). This preparation may, in particular, consist of chemical cleaning, in particular by RCA cleaning (namely a combination of an SC1 bath (NH₄OH, H₂O₂, H₂O), suitable for removing particles and hydrocarbons, and an SC2 bath (HCl, H₂O₂, H₂O), suitable for removing metallic contaminants), a Caro's type clean or Piranhaclean type clean (H₂SO₄:H₂O₂), or even cleaning with an ozone/water (O₃/H₂O) solution. Cleaning may be followed by scrubbing.

In order to increase the bonding energy further, the surface 120a of the substrate 120 may be activated using a plasma treatment (step S2).

The surface 111a of the silicon layer 111 of the initial substrate 110 may be covered with a layer of thermal oxide 114 formed, for example, by oxidizing the surface of the substrate (FIG. 5B, step S3).

The surface 111a of the initial substrate 110, which may optionally be covered with a layer of oxide, may also be activated by plasma treatment (step S4). The bonding surfaces of the substrates 110 and 120 may be activated by exposing them to a plasma based on oxygen, nitrogen, argon, or other. The equipment used for this purpose may, inter alia, have initially been provided for capacitatively coupled reactive ionic etching (RIE), or for etching using inductively coupled plasma (ICP). Further details may, for example, be obtained by referring to the document by Sanz-Velasco et al., entitled “Room temperature wafer bonding using oxygen plasma treatment in reactive ion etchers with and without inductively coupled plasma” (Journal of Electrochemical Society 150, G155, 2003).

The plasma may also be immersed in a magnetic field, in particular, to prevent electrically charged species from diffusing towards the walls of the reactor, using magnetically enhanced reactive ion etching (MERIE) type equipment.

The plasma density may be selected so as to be low, medium or high (or HDP, high-density plasma).

In practice, plasma bonding activation, in general, comprises an initial chemical cleaning such as a RCA clean (namely, a combination of an SC1 bath (NH₄OH, H₂O₂, H₂O) suitable for removing particles and hydrocarbons, and an SC2 bath (HCl, H₂O₂, H₂O) suitable for removing metallic contaminants), followed by exposing the surface to a plasma for a few seconds to a few minutes.

One or more cleaning steps following plasma exposure may be carried out, in particular, in order to remove contaminants introduced during exposure, such as rinsing with water and/or SC1 cleaning, optionally followed by drying by centrifuging. However, cleaning may be replaced by scrubbing in order to eliminate a large proportion of these contaminants.

Activation of a bonding surface by plasma treatment is well known to the skilled person and for the purposes of simplification is not described here in any further detail.

Once prepared, the surfaces 111a and 120a are brought into intimate contact and a pressure is applied to one of the two substrates in order to initiate propagation of a bonding wave between the surfaces in contact (step S5, FIG. 3C).

As is well known, per se, the principle of direct wafer bonding, also known as direct bonding or molecular adhesion, is based on bringing two surfaces into direct contact, i.e., without using a specific material (adhesive, wax, solder, etc.). Such an operation requires that the surfaces for bonding together be sufficiently smooth, free of particles or contamination, and that they come sufficiently close to allow contact to be initiated, typically at a distance of less than a few nanometers. Under such circumstances, the attractive forces between the two surfaces are high enough to cause molecular adhesion (bonding induced by the various attractive forces (Van der Waals forces) of electronic interaction between atoms or molecules of the two surfaces for bonding together).

Before proceeding to thinning the initial substrate 110, the bond is reinforced a first time by carrying out a pre-grinding anneal (step S6). As indicated above, because of the difference in the expansion coefficients of sapphire and silicon, the pre-grinding anneal is carried out at a treatment temperature that is preferably in the range of 150° C. to 180° C. for a period in the range of 30 minutes to 4 hours. This anneal can reduce ring type defects (non-transferred peripheral zone) and prevent delamination of the two substrates during the grinding step.

During pre-grinding annealing, the boat-in temperature of the assembly constituted by bonding the initial substrate 110 to the support substrate 120 is preferably less than 80° C., for example, 50° C. Once the assembly has been introduced into the annealing furnace, the temperature ramp-up, i.e., the rate of increase of temperature used to bring the temperature of the furnace from the boat-in temperature to the temperature proper of the pre-grinding annealing treatment (preferably in the range of 150° C. to 180° C.) is preferably of the order of 1° C./minute. Such control of the boat-in temperature and the temperature ramp-up can reduce the thermal stresses applied to the assembly during the pre-grinding anneal.

Production of the heterostructure continues by thinning the initial substrate 110 in order to form a transferred layer corresponding to a portion of the silicon layer 111.

Thinning is initially carried out by grinding a major proportion of the support 113 (step S7, FIG. 3D). In accordance with the invention, grinding is carried out using a “coarse” wheel or grinder 210, i.e., a wheel, the surface or active grinding portion 211 of which comprises abrasive particles having a mean dimension of more than 6.7 μm (or 2000 mesh), preferably of more than 15 μm (or 1000 mesh), and, more preferably, 31 μm (or 500 mesh) or more. The abrasive particles may in particular be diamond particles. By way of example, the reference number of a wheel model marketed by Saint-Gobain and comprising abrasive diamond type particles with a mean dimension of 6.7 μm (or 2000 mesh) is: FINE WHEEL STD—301017:18BB-11-306-B65JP-5MM 11,100×1,197×9,002 MC176261 69014113064 POLISH#3JP1,28BX623D-5MM. The reference number of a wheel model marketed by Saint-Gobain and comprising abrasive diamond type particles with a mean dimension of 44 microns (or 325 mesh) is: COARSE WHEEL STD—223599: 18BB-11-32B69S 11,034×1⅛×9,001 MD15219669014111620 COARSE #3R7B69-⅛.

During grinding, the assembly of the two substrates is held at the back face of the support surface 120 by a support 220, also termed a chuck, comprising a platen 222 that can hold the substrate 120 by suction or by an electrostatic system, for example. During grinding, the support 220 may be stationary while the wheel 210 is driven in rotation about its axis 212. Alternatively, the support 220 may also be movable in rotation about an axis 221, the wheel 210 being either driven or not driven in rotation.

Grinding is carried out by holding the active grinding surface 211 of the wheel 210 against the support 113 of the initial substrate. Because of the large size of the abrasive particles, the support 113 can be attacked effectively without having to apply too high a load F_{A} to the assembly using the wheel 210, which means that the risks of delamination of the two bonded substrates is reduced. For a wheel with a grinding surface or active grinding portion that comprises abrasive particles having a mean dimension of 6.7 microns (or 2000 mesh), the maximum load is approximately 222.5 N (50 pounds (lb)). This maximum load reduces as the size of the abrasive particles increases. As an example, for a wheel with a grinding surface or active grinding portion that comprises abrasive particles having a mean dimension of 44 μm (or 325 mesh), the maximum load is approximately 133.5 N (30 lb).

Grinding is stopped approximately 120 μm from the surface 120a of the sapphire support substrate.

Next, a post-grinding anneal is carried out in order to reinforce the bond and prevent the etching solution from infiltrating into the bonding interface during the second thinning step. Because a coarse wheel or grinder is used during grinding, the remaining portion 113a of the support 113 has a work-hardened surface that is the source of the appearance of crack type defects. In order to prevent the appearance of these defects, the post-grinding annealing temperature is limited to a temperature in the range of 150° C. to 170° C. Post-grinding annealing is carried out over a period in the range of 30 minutes to 4 hours.

Thinning of the initial substrate is continued by etching the remaining portion 113a (step S9, FIG. 5E). This portion may be removed by chemical etching, also termed wet etching, for example, using a TMAH (tetramethylammonium hydroxide) etching solution.

The remaining portion 113a may also be removed by means of reactive ion etching, also termed plasma etching or dry etching. This etching technique is well known to the skilled person. It should be recalled that it is a physico-chemical etching employing both ion bombardment and a chemical reaction between the ionized gas and the surface of the wafer or the layer to be etched. The atoms of the gas react with the atoms of the layer or the wafer to form a new volatile species that is evacuated by a pumping device.

The oxide layer 112 is used as a stop layer for etching. After etching, the layer 112 may be removed (step S10, FIG. 5G), for example, by HF deoxidation, in order to leave a transferred layer 115 corresponding to at least a portion of the silicon layer 111. However, if required, the oxide layer 112 may be conserved.

Optionally, the structure may be trimmed in order to remove chamfers or edge roll-off present at the periphery of the substrates (step S11). Alternatively, trimming may be carried out on the silicon substrate directly after assembling it with the sapphire substrate, and before the grinding step. As can be seen in FIG. 5G, a heterostructure comprising the sapphire support substrate 120 and the transferred layer 115 is thus obtained, with an interposed buried oxide layer 114.

1. A method of producing a silicon-on-sapphire heterostructure comprising:
bonding a silicon-on-insulator substrate onto a sapphire substrate to form a bonded heterostructure; and
thinning the SOI substrate after forming the bonded heterostructure, comprising:
grinding the SOI substrate using a wheel with a grinding surface comprising abrasive particles having a mean dimension of more than 6.7 μm;
annealing the bonded heterostructure in a post-grinding annealing process at a maximum temperature in a range extending from 150° C. to 170° C. after grinding the SOI substrate; and
etching the SOI substrate after annealing the bonded heterostructure.

2. The method of claim 1, further comprising annealing the bonded heterostructure in a pre-grinding annealing process at a maximum temperature in a range extending from 150° C. to 180° C. prior to thinning the SOI substrate.

3. The method of claim 2, wherein an initial annealing temperature of the bonded heterostructure during the pre-grinding annealing process is less than 80° C.

4. The method claim 3, further comprising ramping up the temperature during the pre-grinding annealing process at a rate of about 1° C./min.

5. The method of claim 1, further comprising forming a layer of oxide on a bonding surface of the silicon-on-insulator substrate prior to bonding the silicon-on-insulator substrate onto the sapphire substrate.

6. The method of claim 1, further comprising activating a bonding surface of at least one of the silicon-on-insulator substrate and the sapphire substrate prior to bonding the silicon-on-insulator substrate onto the sapphire substrate.

7. The method of claim 1, wherein etching the SOI substrate comprising using a chemical etching solution in a wet chemical etching process.

8. The method of claim 1, wherein etching the SOI substrate comprises using reactive ion etching in a dry etching process.

9. The method of claim 1, wherein grinding the SOI substrate further comprises using a wheel with a grinding surface comprising abrasive particles having a mean dimension of 15 μm or more.

10. The method of claim 9, wherein grinding the SOI substrate further comprises using a wheel with a grinding surface comprising abrasive particles having a mean dimension of 31 μm or more.

11. The method of claim 1, wherein grinding the SOI substrate comprises applying a load to the wheel of 222.5 N or less.
